(19) United States
(12) Patent Application Publication
(10) Pub. No.: US 2025/0167764 A1
(43) Pub. Date: May 22, 2025

(54) VARIABLE INDUCTANCE CIRCUIT

(71) Applicant: Qorvo US, Inc., Greensboro, NC (US)

(72) Inventors: Nadim Khlat, Cugnaux (FR); Yazid Yusuf, Orlando, FL (US)

(21) Appl. No.: 18/931,248

(22) Filed: Oct. 30, 2024

Related U.S. Application Data
(60) Provisional application No. 63/599,608, filed on Nov. 16, 2023.

(51) Int. Cl. H03H 9/54; H03H 9/205; H03H 9/56

(52) U.S. Cl. CPC H03H 9/542; H03H 9/205; H03H 9/568

(57) ABSTRACT

A variable inductance circuit is provided. Notably, the variable inductance circuit can be provided in a wireless device in places where a variable inductance and/or capacitance is deemed desirable for specific types of operating scenarios. Herein, the variable inductance circuit includes an impedance inverter circuit and a variable capacitance circuit that can be provided in various topologies between a first terminal and a second terminal. The variable capacitance circuit is configured to cause the variable inductance circuit to present a variable inductance within a target frequency range between the first terminal and the second terminal. By configuring the variable inductance circuit to provide a desired inductance(s) at a place(s) as needed, it is possible to improve performance (e.g., signal rejection, impedance matching, etc.) without increasing a footprint of the wireless device.

### RELATED APPLICATIONS

This application claims the benefit of U.S. provisional patent application Ser. No. 63/599,608, filed on Nov. 16, 2023, the disclosure of which is hereby incorporated herein by reference in its entirety.

### FIELD OF THE DISCLOSURE

The technology of the disclosure relates generally to a circuit configured to present a variable inductance within a target frequency range.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as Surface Acoustic Wave (SAW) resonators and Bulk Acoustic Wave (BAW) resonators, are used in many high-frequency communication applications. In particular, SAW resonators are often employed in filter networks that operate at frequencies up to 1.8 GHz, and BAW resonators are often employed in filter networks that operate at frequencies above 1.5 GHz. Such SAW and BAW-based filters have flat passbands, steep filter skirts, and squared shoulders at the upper and lower ends of the passbands and provide excellent rejection outside of the passbands. SAW and BAW-based filters also have a relatively low insertion loss, tend to decrease in size as the frequency of operation increases, and are relatively stable over wide temperature ranges.

As such, SAW and BAW-based filters are the filters of choice for many wireless devices. Most of these wireless devices support cellular, wireless fidelity (Wi-Fi), Bluetooth, and/or near field communications on the same wireless device and, as such, pose extremely challenging filtering demands. While these demands keep raising the complexity of wireless devices, there is a constant need to improve the performance of acoustic resonators and filters that are based thereon.

### SUMMARY

Aspects disclosed in the detailed description include a variable inductance circuit. Notably, the variable inductance circuit can be provided in a wireless device in places where a variable inductance and/or capacitance is deemed desirable for specific types of operating scenarios. As an example, the variable inductance circuit can be coupled in parallel to an acoustic resonator in an acoustic ladder network to help offset an inherent capacitance of the acoustic resonator. Herein, the variable inductance circuit includes an impedance inverter circuit and a variable capacitance circuit that can be provided in various topologies between a first terminal and a second terminal. The variable capacitance circuit is configured to cause the variable inductance circuit to present a variable inductance within a target frequency range between the first terminal and the second terminal. By configuring the variable inductance circuit to provide a desired inductance(s) at a place(s) as needed, it is possible to improve performance (e.g., signal rejection, impedance matching, etc.) without increasing a footprint of the wireless device.

In one aspect, a variable inductance circuit is provided. The variable inductance circuit includes a first terminal and a second terminal. The variable inductance circuit also includes an impedance inverter circuit. The impedance inverter circuit includes an input node coupled to the first terminal. The impedance inverter circuit also includes an output node coupled to the second terminal. The impedance inverter circuit also includes an intermediate node coupled to a selected one of the first terminal and the second terminal. The variable inductance circuit also includes a variable capacitance circuit. The variable capacitance circuit is coupled between the impedance inverter circuit and the selected one of the first terminal and the second terminal and further to the intermediate node. The variable inductance circuit is configured to present a variable capacitance between the impedance inverter circuit and the selected one of the first terminal and the second terminal to thereby cause a variable inductance between the first terminal and the second terminal within a target frequency range.

In another aspect, an acoustic ladder network is provided. The acoustic ladder network includes at least one acoustic resonator. The at least one acoustic resonator is configured to resonate at a series resonance frequency range to pass a signal from a signal input to a signal output. The at least one acoustic resonator is also configured to resonate at a parallel resonance frequency range outside the series resonance frequency range to block the signal between the signal input and the signal output. The acoustic ladder network also includes a variable inductance circuit. The variable inductance circuit includes a first terminal coupled to the signal input and a second terminal coupled to the signal output. The variable inductance circuit also includes an impedance inverter circuit. The impedance inverter circuit includes an input node coupled to the first terminal. The impedance inverter circuit also includes an output node coupled to the second terminal. The impedance inverter circuit also includes an intermediate node coupled to a selected one of the first terminal and the second terminal. The variable inductance circuit also includes a variable capacitance circuit. The variable capacitance circuit is coupled between the impedance inverter circuit and the selected one of the first terminal and the second terminal and further to the intermediate node. The variable inductance circuit is configured to present a variable capacitance between the impedance inverter circuit and the selected one of the first terminal and the second terminal to thereby cause a variable inductance between the first terminal and the second terminal to thereby offset an electrical capacitance associated with the at least one acoustic resonator within a target frequency range.

In another aspect, a wireless device is provided. The wireless device includes an acoustic ladder network. The acoustic ladder network includes at least one acoustic resonator. The at least one acoustic resonator is configured to resonate at a series resonance frequency range to pass a signal from a signal input to a signal output. The at least one acoustic resonator is also configured to resonate at a parallel resonance frequency range outside the series resonance frequency range to block the signal between the signal input and the signal output. The acoustic ladder network also includes a variable inductance circuit. The variable inductance circuit includes a first terminal coupled to the signal input and a second terminal coupled to the signal output. The variable inductance circuit also includes an impedance inverter circuit. The impedance inverter circuit includes an input node coupled to the first terminal. The impedance inverter circuit also includes an output node coupled to the second terminal. The impedance inverter circuit also includes an intermediate node coupled to a selected one of the first terminal and the second terminal. The variable inductance circuit also includes a variable capacitance circuit. The variable capacitance circuit is coupled between the impedance inverter circuit and the selected one of the first terminal and the second terminal and further to the intermediate node. The variable inductance circuit is configured to present a variable capacitance between the impedance inverter circuit and the selected one of the first terminal and the second terminal to thereby cause a variable inductance between the first terminal and the second terminal to thereby offset an electrical capacitance associated with the at least one acoustic resonator within a target frequency range.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary variable inductance circuit that can be configured according to various embodiments of the present disclosure to present a variable inductance between a first terminal and a second terminal;

FIGS. 2A-2C are schematic diagrams providing exemplary illustrations of the variable inductance circuit of FIG. 1 configured according to one embodiment of the present disclosure;

FIGS. 3A-3D are schematic diagrams providing exemplary illustrations of the variable inductance circuit of FIG. 1 configured according to alternative embodiments of the present disclosure;

FIG. 4 is a schematic diagram of an exemplary variable inductance circuit configured according to another embodiment of the present disclosure;

FIG. 5 is a schematic diagram of an exemplary acoustic ladder network wherein the variable inductance circuits of FIGS. 1 and 4 can be provided; and

FIG. 6 is a schematic diagram of an exemplary communication device wherein the variable inductance circuit of FIGS. 1, 3A-3D, and 4 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a variable inductance circuit. Notably, the variable inductance circuit can be provided in a wireless device in places where a variable inductance and/or capacitance is deemed desirable for specific types of operating scenarios. As an example, the variable inductance circuit can be coupled in parallel to an acoustic resonator in an acoustic ladder network to help offset an inherent capacitance of the acoustic resonator. Herein, the variable inductance circuit includes an impedance inverter circuit and a variable capacitance circuit that can be provided in various topologies between a first terminal and a second terminal. The variable capacitance circuit is configured to cause the variable inductance circuit to present a variable inductance within a target frequency range between the first terminal and the second terminal. By configuring the variable inductance circuit to provide a desired inductance(s) at a place(s) as needed, it is possible to improve performance (e.g., signal rejection, impedance matching, etc.) without increasing a footprint of the wireless device.

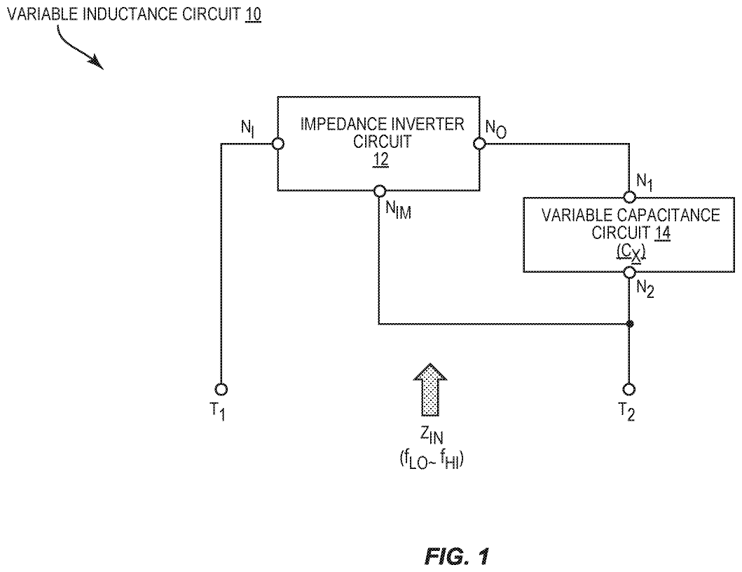

FIG. 1 is a schematic diagram of an exemplary variable inductance circuit 10 that can be configured according to various embodiments of the present disclosure to present a variable inductance Z_{IN} between a first terminal T₁ and a second terminal T₂. Herein, the variable inductance circuit 10 includes an impedance inverter circuit 12 and a variable capacitance circuit 14 that are coupled in series between the first terminal T₁ and the second terminal T₂.

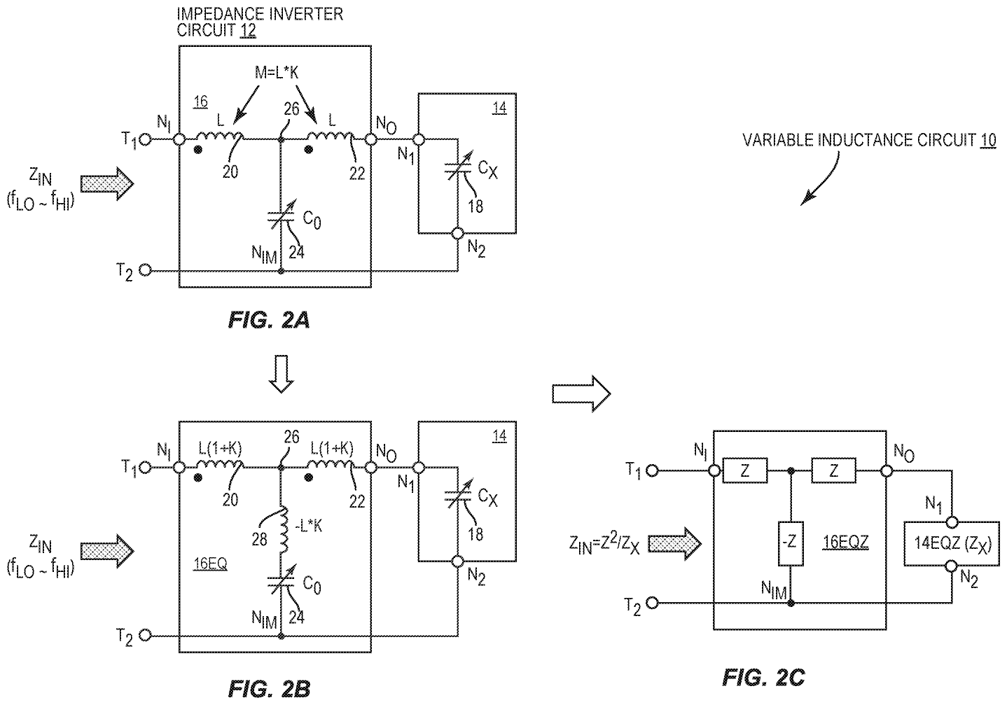

More specifically, the impedance inverter circuit 12 includes an input node N_{I}, an output node N_{O}, and an intermediate node N_{IM}, and the variable capacitance circuit 14 includes a first node N₁ and a second node N₂. According to the embodiment shown herein, the input node N_{I} is coupled to the first terminal T₁, the output node N_{O} is coupled to the first node N₁, the intermediate node N_{IM} is coupled to both the second node N₂ and the second terminal T₂. In this regard, the variable capacitance circuit 14 can be configured to provide a variable capacitance C_{X} between the output node N_{O} and the second terminal T₂ to thereby cause the variable inductance circuit 10 to present the variable inductance Z_{IN} between the first terminal T₁ and the second terminal T₂. As further explained below in FIGS. 2A-2C, the variable capacitance C_{X} can be tuned to cause the variable inductance circuit 10 to present the variable inductance Z_{IN} within a target frequency range bounded by a lower frequency f_{LO} and a higher frequency f_{HI}.

FIGS. 2A-2C are schematic diagrams providing exemplary illustrations of the variable inductance circuit 10 of FIG. 1 configured according to an embodiment of the present disclosure. Common elements between FIGS. 1 and 2A-2C are shown therein with common element numbers and will not be re-described herein.

FIG. 2A illustrates the variable inductance circuit 10 of FIG. 1 wherein the impedance inverter circuit 12 is implemented by an inductor network 16 and the variable capacitance circuit 14 is implemented by a variable capacitor 18. Specifically, the inductor network 16 includes a first inductor 20, a second inductor 22, and a tunable capacitor 24. The first inductor 20 is coupled between the input node N_{I} and a middle node 26. The second inductor 22 is coupled between the middle node 26 and the output node N_{O}. The tunable capacitor 24 is coupled between the middle node 26 and the intermediate node N_{IM}. Each of first inductor 20 and the second inductor 22 has an inductance L and collectively provide a mutual inductance M based on a coupling factor K (0<K<1). The tunable capacitor 24 can be tuned to provide a capacitance C₀.

The variable capacitor 18 is coupled between the first node N₁ and the second node N₂. As illustrated herein, the first node N₁ is coupled to the output node N_{O} and the second node N₂ is coupled to both the second terminal T₂ and the intermediate node N_{IM}. The variable capacitor 18 can be adjusted to provide the variable capacitance C_{X}. As discussed below, the variable capacitance C_{X} will affect the variable inductance Z_{IN}, the lower frequency f_{LO}, and the higher frequency f_{HI}.

In an alternative embodiment, the tunable capacitor 24 and the variable capacitor 18 can each be replaced by a pair of non-inverted ferroelectric acoustic resonators (not shown). The non-inverted ferroelectric acoustic resonators can be tuned to exhibit the capacitance C₀ and the variable capacitance C_{X}, respectively, via an external tuning voltage.

FIG. 2B shows an equivalent electrical model 16EQ of the inductor network 16 in FIG. 2A. In the equivalent electrical model 16EQ, each of the first inductor 20 and the second inductor 22 can have an inductance L (1+K). The equivalent electrical model 16EQ further includes a third inductor 28 that is coupled between the middle node 26 and the tunable capacitor 24. The third inductor 28 has an inductance that equals −L*K.

To help analyze the operating rational behind the variable inductance circuit 10, the equivalent electrical model 16EQ and the variable capacitance circuit 14 in FIG. 2B can be further transformed into an equivalent inductive impedance model 16EQZ and an equivalent capacitive impedance model 14EQZ in FIG. 2C, respectively. Herein, each of the first inductor 20 and the second inductor 22 is represented by an equivalent inductive impedance (Z), the third inductor 28 and the tunable capacitor 24 are collectively represented by an equivalent negative inductive impedance (−Z), and the variable capacitor 18 is represented by an equivalent capacitive impedance (Z_{X}).

The variable inductance Z_{IN} can thus be expressed in equation (Eq. 1) below.

$${Z}_{IN} = {Z}^{2} / {Z}_{X} \qquad ( Eq . 1 )$$

Notably, the impedance inverter circuit 12 will provide an ideal impedance inversion when the capacitance C₀ of the tunable capacitor 24 is shown in equation (Eq. 2).

$${C}_{0} = 1 / ( L * {ω}_{i}^{2} ) \qquad ( Eq . 2 )$$

In the equation (Eq. 2), ω_{I} is a pulsation frequency at which the impedance inverter circuit 12 can provide the perfect impedance inversion. The variable inductance Z_{IN} can be further expanded as in equation (Eq. 3) below.

$${Z}_{IN} = j * L * ω * [ 1 - {K}^{2} = [ ( 1 + K ) / ( {C}_{0} / 2 ) + 1 / {C}_{X} ] * ( 1 / L ) * ( 1 / {ω}^{2} ) + 1 / {( L * {C}_{0} * {C}_{X} * {ω}^{2} )}^{2} ] / [ 1 - 1 / L * ( 1 / {C}_{0} + 1 / {C}_{X} ) * ( 1 / {ω}^{2} ) ] \qquad ( Eq . 3 )$$

In an idealistic situation wherein the coupling factor K is equal to 1, the equation (Eq. 3) can be further simplified as equation (Eq. 4).

$${Z}_{IN} = \text{} [ j * 1 / ( {C}_{0} * {C}_{X} / ( 4 * {C}_{X} + {C}_{0} ) ) \text{} * 1 / ω \text{]*[} - 1 + 1 / ( L * \text{} ( 4 * {C}_{X} + {C}_{0} ) * {ω}^{2} ) \text{]/[} 1 - 1 / ( L * {C}_{0} * {C}_{X} / ( {C}_{0} + {C}_{X} ) ) * {ω}^{2} ] \text{} \qquad ( Eq . 4 )$$

The equation (Eq. 4) further defines the lower frequency f_{LO} (Eq. 5.1) and the higher frequency f_{HI} (Eq. 5.2) that collectively define the target frequency range.

$${F}_{LO} {=}^{def} L * ( 4 * {C}_{X} + {C}_{0} ) \qquad ( Eq . 5.1 )$$

$${f}_{HI} {=}^{def} L * {C}_{X} * {C}_{0} / ( {C}_{X} + {C}_{0} ) \qquad ( Eq . 5.2 )$$

When the target frequency range falls within the lower frequency f_{LO} and the higher frequency f_{HI}, the first term [−1+1/(L*(4*C_{X}+C₀)*ω²)] and the second term [1−1/(L*C₀*C_{X}/(C₀+C_{X}))*ω²] are both positive. As a result, the variable inductance Z_{IN} will exhibit a sort of negative capacitance.

As shown in equation (Eq. 2), the impedance inverter circuit 12 will provide the ideal impedance inversion at an ideal frequency 1/ω_{ideal}²=L*C₀. Accordingly, a reactance is equal to 1/(j*ω_{ideal}*C₀)=−j*L*ω_{ideal}. The variable impedance Z_{IN}, as shown in equation (Eq. 1), will be further expressed by equation (Eq. 6).

$$\begin{matrix}{Z}_{IN} = {Z}^{2} / {Z}_{X} = - {( j * L ( 1 + K ) * {ω}_{ideal} )}^{2} * j * {C}_{X} * {ω}_{ideal} \\ = j * L * {( 1 + K )}^{2} * {C}_{X} / {C}_{0} * {ω}_{ideal}\end{matrix} \qquad ( Eq . 6 )$$

Thus, according to equation (Eq. 6), the variable capacitance C_{X} not only defines the lower frequency f_{LO} and the higher frequency f_{HI}, but also affects the variable inductance Z_{IN} presented by the variable inductance circuit 10 between the first terminal T₁ and the second terminal T₂. In this regard, it is possible to configure the variable capacitance circuit 14 to present the variable capacitance C_{X} to thereby cause the variable inductance circuit 10 to present the variable inductance Z_{IN} within the target frequency range defined by the lower frequency f_{LO} and the higher frequency f_{HI}.

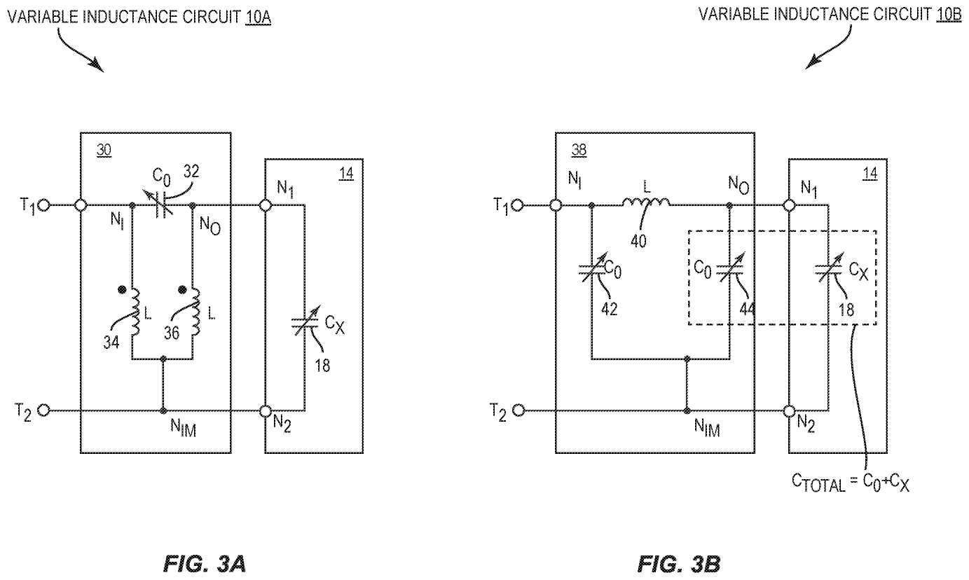

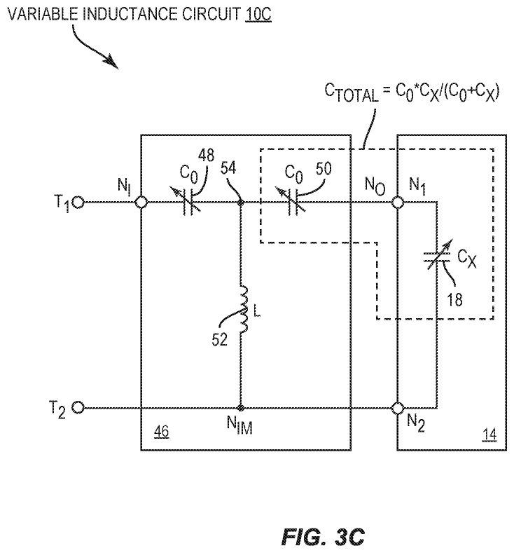

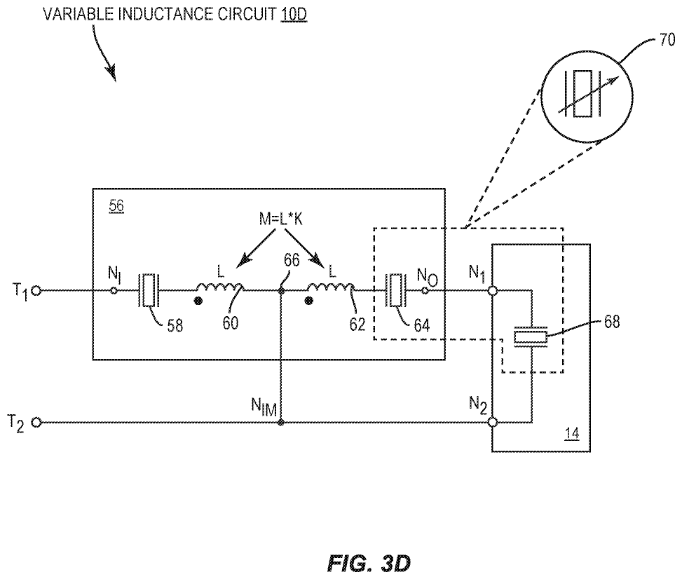

The impedance inverter circuit 12 in the variable inductance circuit 10 of FIG. 1 can be configured according to various alternative topologies without affecting the behavior of the variable inductance circuit 10. In this regard, FIGS. 3A-3D are schematic diagrams providing exemplary illustrations of alternative configurations of the impedance inverter circuit 12 in FIG. 1. Common elements between FIGS. 1, 2A, and 3A-3D are shown therein with common element numbers and will not be re-described herein.

FIG. 3A illustrates a variable inductance circuit 10A including an impedance inverter circuit 30 configured according to an alternative embodiment of the present disclosure. Herein, the impedance inverter circuit 30 includes a capacitor 32, a first inductor 34, and a second inductor 36. The capacitor 32 is coupled between the input node N_{I} and the output node N_{O} and can be tuned to the capacitance C₀. The first inductor 34 is coupled between the input node N_{I} and the intermediate node N_{IM}. The second inductor 36 is coupled between the output node N_{O} and the intermediate node N_{IM}. Each of the first inductor 34 and the second inductor 36 has the inductance L. The variable capacitance circuit 14 includes the variable capacitor 18. The variable capacitor 18 is coupled between the first node N₁, which further couples to the output node N_{O}, and the second node N₂ that further couples to the intermediate node N_{IM} and the second terminal T₂.

FIG. 3B illustrates a variable inductance circuit 10B including an impedance inverter circuit 38 configured according to another alternative embodiment of the present disclosure. Herein, the impedance inverter circuit 38 includes an inductor 40, a first capacitor 42, and a second capacitor 44. Specifically, the inductor 40 is coupled between the input node N_{I} and the output node N_{O}, the first capacitor 42 is coupled between the input node N_{I} and the intermediate node N_{IM}, and the second capacitor 44 is coupled between the output node N_{O} and the intermediate node N_{IM}. Herein, the inductor 40 has the inductance L, and each of the first capacitor 42 and the second capacitor 44 can be tuned to the capacitance C₀. The variable capacitance circuit 14 includes the variable capacitor 18. The variable capacitor 18 is coupled between the first node N₁, which further couples to the output node N_{O}, and the second node N₂, which further couples to the intermediate node N_{IM} and the second terminal T₂.

In an embodiment, the second capacitor 44 and the variable capacitor 18 can be replaced by a capacitor C_{TOTAL}. Given that the second capacitor 44 and the variable capacitor 18 are provided in parallel between the output node N_{O} and the intermediate node N_{IM}, the capacitor C_{TOTAL} will have a respective capacitance that equals a sum of the capacitance C₀ of the second capacitor 44 and the variable capacitance C_{X} of the variable capacitor 18 (C_{TOTAL}=C₀+C_{X}).

FIG. 3C illustrates a variable inductance circuit 10C including an impedance inverter circuit 46 configured according to another alternative embodiment of the present disclosure. Herein, the impedance inverter circuit 46 includes a first capacitor 48, a second capacitor 50, and an inductor 52. Specifically, the first capacitor 48 and the second capacitor 50 are coupled in series between the input node N_{I} and the output node N_{O}, and the inductor 52 is coupled between a middle node 54 and the intermediate node N_{IM}. Herein, the inductor 52 has the inductance L, and each of the first capacitor 48 and the second capacitor 50 can be tuned to the capacitance C₀. The variable capacitance circuit 14 includes the variable capacitor 18. The variable capacitor 18 is coupled between the first node N₁, which further couples to the output node N_{O}, and the second node N₂, which further couples to the intermediate node N_{IM} and the second terminal T₂.

In an embodiment, the second capacitor 50 and the variable capacitor 18 can be replaced by a capacitor C_{TOTAL}. Given that the second capacitor 50 and the variable capacitor 18 are provided in series between the output node N_{O} and the intermediate node N_{IM}, the capacitor C_{TOTAL} will have a respective capacitance expressed as C_{TOTAL}=C₀*C_{X}/(C₀+C_{X}).

FIG. 3D illustrates a variable inductance circuit 10D including an impedance inverter circuit 56 configured according to another alternative embodiment of the present disclosure. Herein, the impedance inverter circuit 56 includes a first acoustic resonator 58, a pair of negatively coupled inductors 60, 62, and a second acoustic resonator 64 that are coupled in series between the input node N_{I} and the output node N_{O}. A middle node 66, which is located in between the negatively coupled inductors 60, 62, is coupled directly to the intermediate node N_{IM}.

The variable capacitance circuit 14 can be configured to include a tunable acoustic resonator 68. The tunable acoustic resonator 68 is coupled between the first node N₁, which further couples to the output node N_{O}, and the second node N₂, which further couples to the intermediate node N_{IM} and the second terminal T₂. In an embodiment, it is also possible to replace the second acoustic resonator 64 and the tunable acoustic resonator 68 with a single tunable acoustic resonator 70.

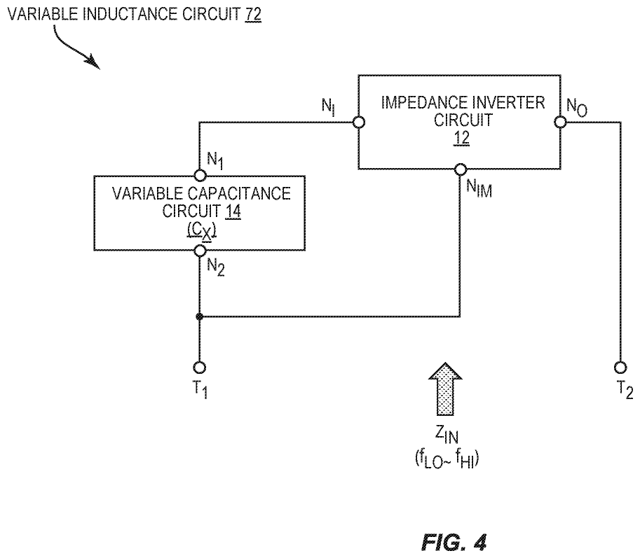

Recall that in FIG. 1, the variable capacitance circuit 14 is coupled between the output node N_{O} and the second terminal T₂. In an alternative embodiment, the variable capacitance circuit 14 can also be coupled between the input node N_{I} and the first terminal T₁. In this regard, FIG. 4 is a schematic diagram of an exemplary variable inductance circuit 72 configured according to one embodiment of the present disclosure. Common elements between FIGS. 1 and 4 are shown therein with common element numbers and will not be re-described herein.

Herein, the first node N₁ of the variable capacitance circuit 14 is coupled to the input node N_{I}, and the second node N₂ of the variable capacitance circuit 14 is coupled to the first terminal T₁ and the intermediate node N_{IM}. The output node N_{O}, on the other hand, is coupled directly to the second terminal T₂. Notably, the variable inductance circuit 72 is functionally equivalent to the variable inductance circuit 10 of FIG. 1. In other words, the variable inductance circuit 72 and the variable inductance circuit 10 are interchangeable.

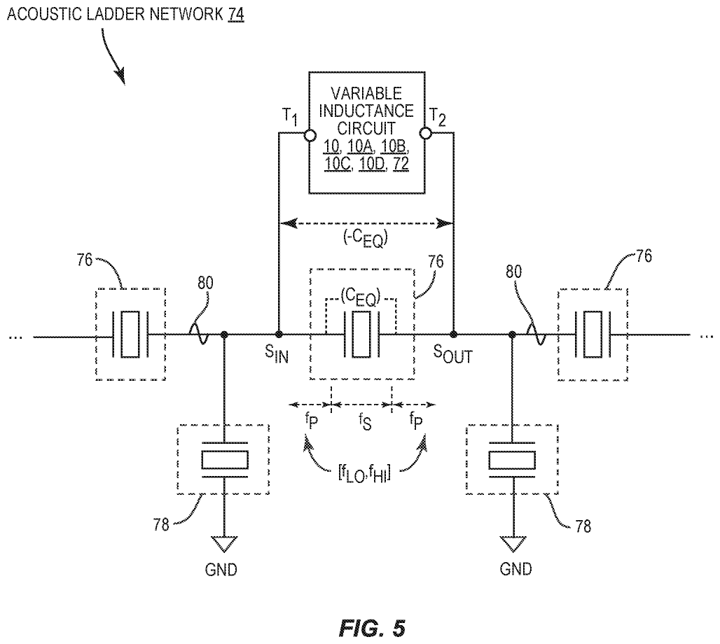

The variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and the variable inductance circuit 72 of FIG. 4 can be provided in a wireless device in places where a variable inductance and/or capacitance is deemed desirable for specific types of operating scenarios. In a non-limiting example, FIG. 5 is a schematic diagram of an exemplary acoustic ladder network 74 wherein the variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and/or the variable inductance circuit 72 of FIG. 4 can be provided.

Herein, the acoustic ladder network 74 includes multiple series acoustic resonators 76 and multiple shunt acoustic resonators 78 that are arranged as illustrated. Each of the series acoustic resonators 76 is configured to resonate in a series resonance frequency range f_{S} (a.k.a. passband frequency range) to pass a signal 80 from a signal input S_{IN} to a signal output S_{OUT}. Each of the series acoustic resonators 76 is further configured to block the signal 80 between the signal input S_{IN} and the signal output S_{OUT} in a parallel resonance frequency range f_{P} (a.k.a. stopband frequency range) that does not overlap with the series resonance frequency range f_{S}.

Notably, each of the series acoustic resonators 76 is typically made with a pair of metal electrodes that can present an equivalent electrical capacitance C_{EQ} in the parallel resonance frequency range f_{P}. The electrical capacitance C_{EQ} can cause each of the series acoustic resonators 76 to resonate across the parallel resonance frequency range f_{P}, thus resulting in parallel resonance in each of the series acoustic resonators 76. Consequently, each of the series acoustic resonators 76 may not be able to effectively block the signal 80 across the parallel resonance frequency range f_{P}, thus compromising performance of the acoustic ladder network 74. As such, it is desired to eliminate the electrical capacitance C_{EQ} across the parallel resonance frequency range f_{P}.

In this regard, the variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and/or the variable inductance circuit 72 of FIG. 4 (hereinafter collectively referred to as “variable inductance circuit” for brevity) can be provided in parallel to at least one of the series acoustic resonators 76 to help offset the electrical capacitance C_{EQ} in a target frequency range (f_{LO}, f_{HI}) that overlaps with or falls within the parallel resonance frequency range f_{P}.

Specifically, the first terminal T₁ of the variable inductance circuit is coupled to the signal input S_{IN} and the second terminal T₂ of the variable inductance circuit is coupled to the signal output S_{OUT}. In an embodiment, the variable inductance circuit can be configured accordingly to present the variable inductance Z_{IN} as a negative capacitance −C_{EQ} to help offset the equivalent electrical capacitance C_{EQ} in the target frequency range.

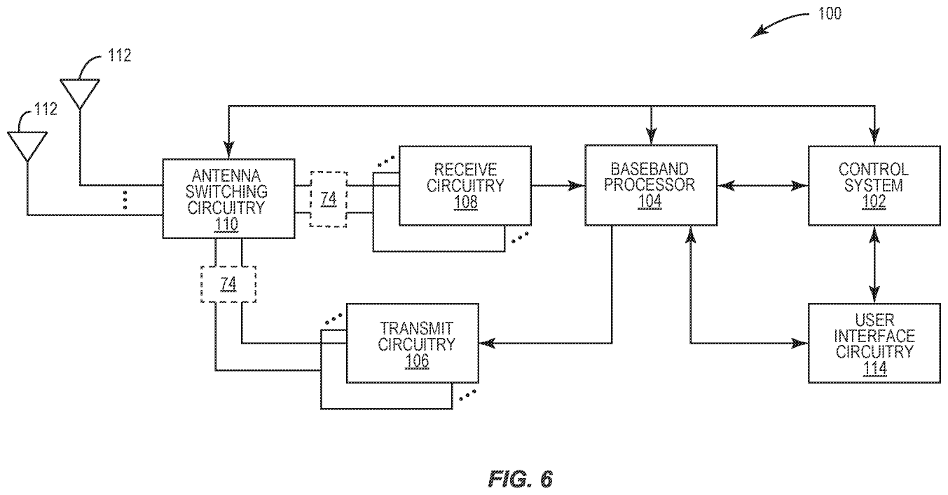

The variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and the variable inductance circuit 72 of FIG. 4 can be provided in a communication device to support the embodiments described above. In this regard, FIG. 6 is a schematic diagram of an exemplary communication device 100 wherein the variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and the variable inductance circuit 72 of FIG. 4 can be provided.

Herein, the communication device 100 can be any type of communication devices, such as mobile terminals, smart watches, tablets, computers, navigation devices, access points, and like wireless communication devices that support wireless communications, such as cellular, wireless local area network (WLAN), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In a non-limiting example, the variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and the variable inductance circuit 72 of FIG. 4 can be provided in the control system 102, the baseband processor 104, the transmit circuitry 106, the receive circuitry 108, the antenna switching circuitry 110, and/or the user interface circuitry 114. In another non-limiting example, the acoustic ladder network 74 of FIG. 5, which may include the variable inductance circuit 10 of FIG. 1, the variable inductance circuit 10A of FIG. 3A, the variable inductance circuit 10B of FIG. 3B, the variable inductance circuit 10C of FIG. 3C, the variable inductance circuit 10D of FIG. 3D, and/or the variable inductance circuit 72 of FIG. 4, can be provided in the antenna switching circuitry 110. In another non-limiting example, the acoustic ladder network 74 may be provided between the transmit circuitry 106 and the antenna switching circuitry 110 and/or between the receive circuitry 108 and the antenna switching circuitry 110.

Those skilled in the art will recognize improvements and modifications to the embodiments of the present disclosure. All such improvements and modifications are considered within the scope of the concepts disclosed herein and the claims that follow.

What is claimed is:

1. A variable inductance circuit comprising:
a first terminal and a second terminal;
an impedance inverter circuit comprising an input node coupled to the first terminal, an output node coupled to the second terminal, and an intermediate node coupled to a selected one of the first terminal and the second terminal; and
a variable capacitance circuit coupled between the impedance inverter circuit and the selected one of the first terminal and the second terminal and further to the intermediate node, the variable inductance circuit is configured to present a variable capacitance between the impedance inverter circuit and the selected one of the first terminal and the second terminal to thereby cause a variable inductance between the first terminal and the second terminal within a target frequency range.

2. The variable inductance circuit of claim 1, wherein the target frequency range is bounded by a lower frequency and a higher frequency each as a function of the variable capacitance.

3. The variable inductance circuit of claim 1, wherein:
the input node is coupled to the first terminal; and
the variable capacitance circuit has a first node coupled to the output node and a second node coupled to the second terminal and the intermediate node.

4. The variable inductance circuit of claim 3, wherein:
the impedance inverter circuit comprises:
a pair of negatively coupled inductors provided in series between the input node and the output node; and
a capacitor coupled between a middle node and the intermediate node; and
the variable capacitance circuit comprises a variable capacitor coupled between the first node and the second node.

5. The variable inductance circuit of claim 3, wherein:
the impedance inverter circuit comprises:
a capacitor coupled between the input node and the output node;
a first inductor coupled between the input node and the intermediate node; and
a second inductor coupled between the output node and the intermediate node; and
the variable capacitance circuit comprises a variable capacitor coupled between the first node and the second node.

6. The variable inductance circuit of claim 3, wherein:
the impedance inverter circuit comprises:
an inductor coupled between the input node and the output node;
a first capacitor coupled between the input node and the intermediate node; and
a second capacitor coupled between the output node and the intermediate node; and
the variable capacitance circuit comprises a variable capacitor coupled between the first node and the second node.

7. The variable inductance circuit of claim 3, wherein:
the impedance inverter circuit comprises:
a first capacitor and a second capacitor coupled in series between the input node and the output node; and
an inductor coupled between a middle node and the intermediate node; and
the variable capacitance circuit comprises a variable capacitor coupled between the first node and the second node.

8. The variable inductance circuit of claim 3, wherein:
the impedance inverter circuit comprises:
a first acoustic resonator, a pair of negatively coupled inductors, and a second acoustic resonator provided in series between the input node and the output node; and
a middle node coupled directly to the intermediate node; and
the variable capacitance circuit comprises a tunable acoustic resonator coupled between the first node and the second node.

9. The variable inductance circuit of claim 8, wherein the second acoustic resonator and the tunable acoustic resonator are combined into a single tunable acoustic resonator.

10. The variable inductance circuit of claim 1, wherein:
the output node is coupled to the second terminal; and
the variable capacitance circuit has a first node coupled to the input node and a second node coupled to the first terminal and the intermediate node.

11. An acoustic ladder network comprising:
at least one acoustic resonator configured to:
resonate at a series resonance frequency range to pass a signal from a signal input to a signal output; and
block the signal between the signal input and the signal output in a parallel resonance frequency range outside the series resonance frequency range; and
a variable inductance circuit comprising:
a first terminal coupled to the signal input and a second terminal coupled to the signal output;
an impedance inverter circuit comprising an input node coupled to the first terminal, an output node coupled to the second terminal, and an intermediate node coupled to a selected one of the first terminal and the second terminal; and
a variable capacitance circuit coupled between the impedance inverter circuit and the selected one of the first terminal and the second terminal and further to the intermediate node, the variable inductance circuit is configured to present a variable capacitance between the impedance inverter circuit and the selected one of the first terminal and the second terminal to thereby cause a variable inductance between the first terminal and the second terminal to thereby offset an electrical capacitance associated with the at least one acoustic resonator within a target frequency range.

12. A wireless device comprising an acoustic ladder network, the acoustic ladder network comprises:
at least one acoustic resonator configured to:
resonate at a series resonance frequency range to pass a signal from a signal input to a signal output; and
block the signal between the signal input and the signal output in a parallel resonance frequency range outside the series resonance frequency range; and
a variable inductance circuit comprising:
a first terminal coupled to the signal input and a second terminal coupled to the signal output;
an impedance inverter circuit comprising an input node coupled to the first terminal, an output node coupled to the second terminal, and an intermediate node coupled to a selected one of the first terminal and the second terminal; and
a variable capacitance circuit coupled between the impedance inverter circuit and the selected one of the first terminal and the second terminal and further to the intermediate node, the variable inductance circuit is configured to present a variable capacitance between the impedance inverter circuit and the selected one of the first terminal and the second terminal to thereby cause a variable inductance between the first terminal and the second terminal to thereby offset an electrical capacitance associated with the at least one acoustic resonator within a target frequency range.

13. The wireless device of claim 12, wherein:
the input node is coupled to the first terminal; and
the variable capacitance circuit has a first node coupled to the output node and a second node coupled to the second terminal and the intermediate node.

14. The wireless device of claim 13, wherein:
the impedance inverter circuit comprises:
a pair of negatively coupled inductors provided in series between the input node and the output node; and
a capacitor coupled between a middle node and the intermediate node; and
the variable capacitance circuit comprises a variable capacitor coupled between the first node and the second node.

15. The wireless device of claim 13, wherein:
the impedance inverter circuit comprises:
a capacitor coupled between the input node and the output node;
a first inductor coupled between the input node and the intermediate node; and
a second inductor coupled between the output node and the intermediate node; and
the variable capacitance circuit comprises a variable capacitor coupled between the first node and the second node.

16. The wireless device of claim 13, wherein:
the impedance inverter circuit comprises:
an inductor coupled between the input node and the output node;
a first capacitor coupled between the input node and the intermediate node; and
a second capacitor coupled between the output node and the intermediate node; and
the variable capacitance circuit comprises a variable capacitor coupled between the first node and the second node.

17. The wireless device of claim 13, wherein:
the impedance inverter circuit comprises:
a first capacitor and a second capacitor coupled in series between the input node and the output node; and
an inductor coupled between a middle node and the intermediate node; and
the variable capacitance circuit comprises a variable capacitor coupled between the first node and the second node.

18. The wireless device of claim 13, wherein:
the impedance inverter circuit comprises:
a first acoustic resonator, a pair of negatively coupled inductors, and a second acoustic resonator provided in series between the input node and the output node; and
a middle node coupled directly to the intermediate node; and
the variable capacitance circuit comprises a tunable acoustic resonator coupled between the first node and the second node.

19. The wireless device of claim 18, wherein the second acoustic resonator and the tunable acoustic resonator are combined into a single tunable acoustic resonator.

20. The wireless device of claim 12, wherein:
the output node is coupled to the second terminal; and
the variable capacitance circuit has a first node coupled to the input node and a second node coupled to the first terminal and the intermediate node.
